(19) United States
(12) Patent Application Publication
(10) Pub. No.: US 2025/0309611 A1
(43) Pub. Date: Oct. 2, 2025

(54) LASER LIGHT EMITTING DEVICE AND OPTICAL DISTANCE MEASUREMENT DEVICE

(71) Applicant: DENSO CORPORATION, Kariya-city (JP)

(72) Inventor: Masato NAKAJIMA, Kariya-city (JP)

(21) Appl. No.: 19/236,122

(22) Filed: Jun. 12, 2025

Related U.S. Application Data
(63) Continuation of application No. PCT/JP2023/041398, filed on Nov. 17, 2023.

(30) Foreign Application Priority Data
Dec. 27, 2022 (JP) 2022-209222

(51) Int. Cl. H01S 5/042; G01R 19/00; G01S 7/481; G01S 7/4865; G01S 17/10

(52) U.S. Cl. CPC H01S 5/042; G01R 19/0092; G01S 7/4814; G01S 7/4817; G01S 7/4865; G01S 17/10

(57) ABSTRACT

A laser light emitting device includes a laser diode, a DC power supply, a booster circuit that boosts a DC voltage supplied from the DC power supply via a main wiring connected to a positive electrode of the DC power supply and supplies boosted DC voltage to the laser diode, a drive wiring that connects the main wiring to a negative electrode of the DC power supply, a drive circuit having a switch that switches between a conducted state and a non-conducted state of the laser diode, a current detection section that detects a current value of DC current flowing on the main wiring in a direction from the DC power supply to the laser diode, a determination section that judges whether the current value is normal or abnormal, and a relay section that cuts off supply of the DC current depending on a determination result of the determination section.

### CROSS REFERENCE TO RELATED APPLICATIONS

This application is a continuation application of International Patent Application No. PCT/JP2023/041398 filed on Nov. 17, 2023, which designated the U.S. and based on and claims the benefits of priority of Japanese Patent Application No. 2022-209222 filed on Dec. 27, 2022. The entire disclosure of all of the above applications is incorporated herein by reference.

### TECHNICAL FIELD

The present disclosure relates to a laser light emitting device and an optical distance measurement device.

### BACKGROUND

A distance measurement device may measure a distance to an object by emitting a laser beam toward the object and then receiving the reflected light from the object, and measuring the time from irradiation to optical reception.

### SUMMARY

According to a first aspect of the present disclosure, there is provided a laser light emitting device. The laser light emitting device includes a laser diode, a DC power supply, a booster circuit that boosts a DC voltage supplied from the DC power supply via a main wiring connected to a positive electrode of the DC power supply and supplies the boosted DC voltage to the laser diode, a drive wiring that connects the main wiring to a negative electrode of the DC power supply, a drive circuit having a switch that switches between a conducted state and a non-conducted state of the laser diode, the series connection of the laser diode and the switch being arranged on the drive wiring, a current detection section that detects a current value of a DC current flowing on the main wiring in a direction from the DC power supply to the laser diode, a determination section that judges whether the current value is normal or abnormal, and a relay section that cuts off the supply of the DC current depending on a determination result of the determination section.

According to a second aspect of the present disclosure, there is provided an optical distance measurement device. This optical distance measurement device includes a laser light emitting device having a laser diode, a light receiver that receives reflected light of the laser light emitted from the laser diode reflected by an object, and a calculator that calculates a distance to the object using the time from when the laser light is emitted to when the reflected light is received. The laser light emitting device includes a DC power supply, a booster circuit that boosts a DC voltage supplied from the DC power supply via a main wiring connected to a positive electrode of the DC power supply and supplies the boosted DC voltage to the laser diode, a drive wiring that connects the main wiring to a negative electrode of the DC power supply, a drive circuit having a switch that switches between a conducted state and a non-conducted state of the laser diode, the series connection of the laser diode and the switch being arranged on the drive wiring, a current detection section that detects a current value of a DC current flowing on the main wiring in a direction from the DC power supply to the laser diode, a determination section that judges whether the current value is normal or abnormal, and a relay section that cuts off the supply of the DC current depending on a determination result of the determination section.

### BRIEF DESCRIPTION OF DRAWINGS

The above and other objects, features and advantages of the present disclosure will become more apparent from the following detailed description made with reference to the accompanying drawings. In the drawings:

FIG. 1 is a diagram showing a configuration of an optical distance measurement device;

FIG. 2 is a circuit diagram showing a configuration of a laser light emitting device according to a first embodiment;

FIG. 3 is a circuit diagram showing a specific example of a current detection unit, a determination unit, and a relay section;

FIG. 4 is a timing chart of a light emission process in the first embodiment;

FIG. 5 is a timing chart of a recovery process;

FIG. 6 is a circuit diagram showing a configuration of a laser light emitting device according to a second embodiment;

FIG. 7 is a timing chart of a light emission process in the second embodiment; and

FIG. 8 is a circuit diagram showing a configuration of a laser light emitting device according to a third embodiment.

### DETAILED DESCRIPTION

In an assumable example, a distance measurement device may measure a distance to an object by emitting a laser beam toward the object and then receiving the reflected light from the object, and measuring the time from irradiation to optical reception. In order to improve distance measurement performance, it may be required to irradiate a high-power laser beam. In order to irradiate a high-power laser beam, it may be necessary to apply a high voltage to the laser diode that emits the laser beam. A booster circuit may be adopted to apply a high voltage to the laser diode. The example describes a booster circuit that uses an inductor, a transistor, a diode, and a resistor to boost a voltage.

However, in the above-mentioned conventional example, when a transistor in the booster circuit shorts out, unintended large current flows from the DC power supply to the laser diode, resulting in the generation of an excessively intense light.

According to a first aspect of the present disclosure, there is provided a laser light emitting device. The laser light emitting device includes a laser diode, a DC power supply, a booster circuit that boosts a DC voltage supplied from the DC power supply via a main wiring connected to a positive electrode of the DC power supply and supplies the boosted DC voltage to the laser diode, a drive wiring that connects the main wiring to a negative electrode of the DC power supply, a drive circuit having a switch that switches between a conducted state and a non-conducted state of the laser diode, the series connection of the laser diode and the switch being arranged on the drive wiring, a current detection section that detects a current value of a DC current flowing on the main wiring in a direction from the DC power supply to the laser diode, a determination section that judges whether the current value is normal or abnormal, and a relay section that cuts off the supply of the DC current depending on a determination result of the determination section.

According to this laser light emitting device, when the current value of the DC current flowing from the DC power supply toward the laser diode is abnormal, the relay section cuts off the DC current, thereby preventing abnormal light emission from the laser diode.

According to a second aspect of the present disclosure, there is provided an optical distance measurement device. This optical distance measurement device includes a laser light emitting device having a laser diode, a light receiver that receives reflected light of the laser light emitted from the laser diode reflected by an object, and a calculator that calculates a distance to the object using the time from when the laser light is emitted to when the reflected light is received. The laser light emitting device includes a DC power supply, a booster circuit that boosts a DC voltage supplied from the DC power supply via a main wiring connected to a positive electrode of the DC power supply and supplies the boosted DC voltage to the laser diode, a drive wiring that connects the main wiring to a negative electrode of the DC power supply, a drive circuit having a switch that switches between a conducted state and a non-conducted state of the laser diode, the series connection of the laser diode and the switch being arranged on the drive wiring, a current detection section that detects a current value of a DC current flowing on the main wiring in a direction from the DC power supply to the laser diode, a determination section that judges whether the current value is normal or abnormal, and a relay section that cuts off the supply of the DC current depending on a determination result of the determination section.

According to this optical distance measurement device, when the current value of the DC current flowing from the DC power supply toward the laser diode is abnormal, the relay section cuts off the DC current, thereby preventing abnormal light emission from the laser diode.

### A. First Embodiment

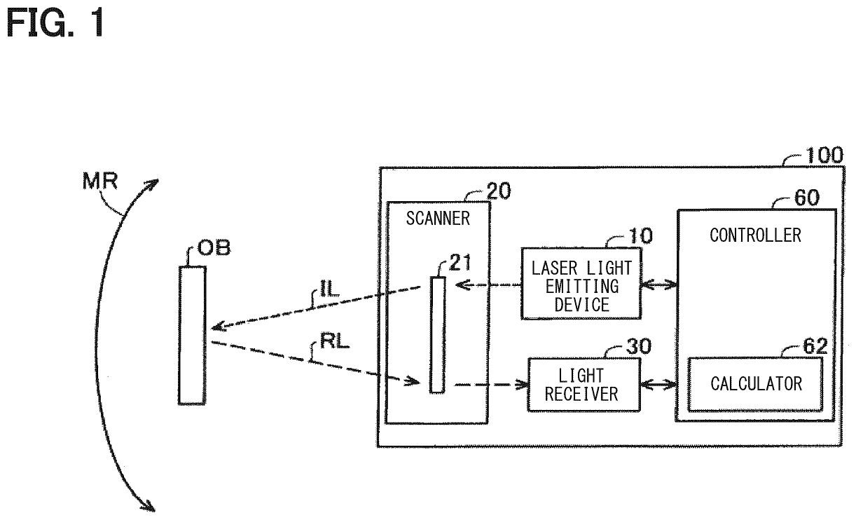

An optical distance measurement device 100 illustrated in FIG. 1 detects a distance to an object OB by emitting laser light IL and receiving reflected light RL reflected by the object OB. The optical distance measurement device 100 is mounted on a vehicle, for example, and is used to measure the distance to the objects present around the vehicle. In the present embodiment, the optical distance measurement device 100 is referred to as a LIDAR (Light Detection And Ranging). The optical distance measurement device 100 includes a laser light emitting device 10, a scanner 20, a light receiver 30 and a controller 60. The laser light emitting device 10 emits laser light IL for ranging. The laser light IL may also be referred to as a laser beam.

The controller 60 includes a computer including, for example, a CPU and a memory. The controller 60 controls the operations of the laser light emitting device 10, the scanner 20 and the light receiver 30. The controller 60 further includes a calculator 62. The calculator 62 calculates the distance to the object OB. The calculator 62 may be operated by the CPU executing a program stored in the memory, or may be operated by an electronic circuit.

The laser light emitting device 10 includes a laser diode that emits pulsed laser light IL. The laser light IL emitted from the laser diode is collimated by a collimating lens (not shown) and enters the scanner 20.

The scanner 20 scans with the laser light IL in an angular range including a predetermined measurement range MR. The scanner 20 includes a mirror 21 and a rotary solenoid (not shown). The mirror 21 reflects the laser light IL, and the rotary solenoid drives the mirror 21. The rotary solenoid repeats a normal rotation and a reverse rotation within a predetermined angular range, so that the laser light IL is scanned within the measurement range MR.

The light receiver 30 receives reflected light RL reflected by the object OB to which the laser light IL is emitted from the laser diode LD. The light receiver 30 outputs a detection signal according to the intensity of the received light to the calculator 62.

The calculator 62 calculates the distance to the object OB by adopting the detection signal received from the light receiver 30. The calculator 62 calculates a distance to the object OB by adopting time of flight (TOF) being a time measured from a moment where the laser light is emitted until a moment where the reflected light is received.

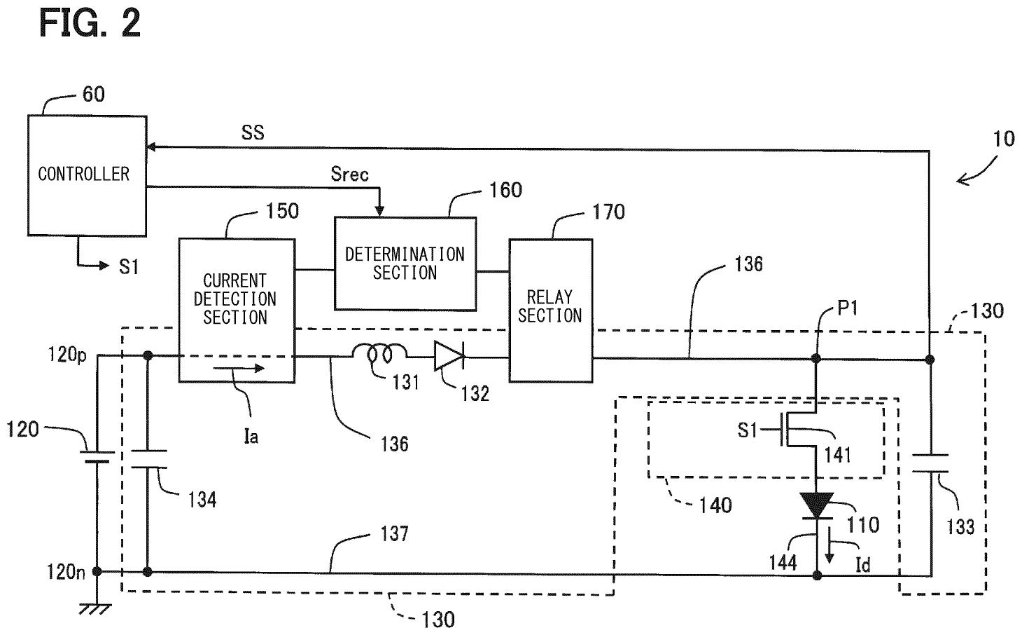

As shown in FIG. 2, the laser light emitting device 10 includes a laser diode 110, a DC power supply 120, a booster circuit 130, a drive circuit 140, a current detection section 150, a determination section 160, and a relay section 170.

The booster circuit 130 boosts the DC voltage supplied from the DC power supply 120 via a main wiring 136 connected to a positive electrode 120p of the DC power supply 120, and supplies the boosted voltage to the laser diode 110. The main wiring 136 is also called a “positive electrode side wiring,” and a wiring 137 connected to a negative electrode 120n of the DC power supply 120 is also called a “negative electrode side wiring.” The main wiring 136 is provided with a boost coil 131 and a forward-connected diode 132, and the diode 132 is disposed downstream of the boost coil 131. In the present disclosure, of any two positions on the main wiring 136, the position closer to the positive electrode 120p of the DC power supply 120 is referred to as the “upstream” position, and the position farther from the positive electrode 120p is referred to as the “downstream” position. A capacitor 133 is connected downstream of the diode 132 between the main wiring 136 and the negative electrode 120n of the DC power supply 120. This capacitor 133 is charged to a high voltage and has the function of increasing the voltage across the laser diode 110. The booster circuit 130 has a function of charging the capacitor 133, and therefore can also be called a “charging circuit.” The booster circuit 130 further includes a capacitor 134 connected in parallel with the DC power supply 120. The capacitor 134 has the function of stabilizing the output voltage of the DC power supply 120. The capacitor 134 may be omitted. The configuration of the booster circuit 130 is just an example, and booster circuits with other configurations may also be used.

The drive circuit 140 has a drive wiring 144 that connects the main wiring 136 and the negative electrode 120n of the DC power supply 120, and a switch 141 that switches the laser diode 110 between a conducting state and a non-conducting state. The switch 141 is connected in series to the laser diode 110 on the drive wiring 144. The switch 141 may be, for example, an N-channel insulated gate field effect transistor (IGFET), or another transistor. The same applies to the other switches described below. A control signal S 1 output from the controller 60 is input to a control terminal of the switch 141.

The current detection section 150 detects the current value of the DC current la flowing in the direction from the DC power supply 120 to the laser diode 110. This DC current la is also called a “coil current” because it flows through the boost coil 131. The determination section 160 determines whether the current value of the DC current la is normal or abnormal. The relay section 170 cuts off the supply of the direct current la in accordance with the result of the determination by a determination section 160. That is, when the current value of the DC current la is within a normal range, the DC current la is not cut off, and when the current value of the DC current la is abnormally large, the DC current la is cut off.

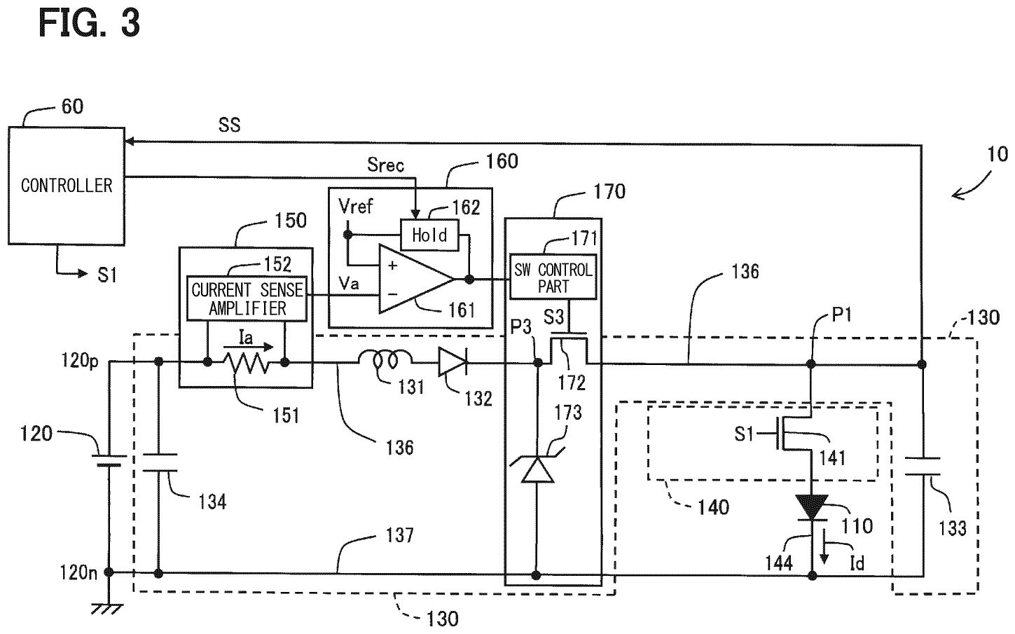

As shown in FIG. 3, the current detection section 150 can be configured to include a shunt resistor 151 and a current sense amplifier 152. The shunt resistor 151 is provided in the main wiring 136. The current sense amplifier 152 outputs a voltage Va proportional to the DC current la flowing through the shunt resistor 151. Hereinafter, the output voltage Va of the current sense amplifier 152 will also be referred to as a “current value of the DC current la.”

The determination section 160 can be configured to include a comparator 161 and a holding part 162. The comparator 161 compares the voltage value Va of the DC current la with a preset reference value Vref, and outputs the result of the comparison. Specifically, the comparator 161 outputs an H-level voltage when the voltage value Va of the DC current la is less than the preset reference value Vref, and outputs an L-level voltage when the voltage value Va of the DC current la is greater than the preset reference value Vref. The reference value Vref is preferably set to a value smaller than an oscillation current threshold of the laser diode 110 and larger than a peak current value of the DC current la when the switch 141 of the drive circuit 140 is operating normally. This point will be discussed further below. During normal operation, the voltage value Va of the DC current la is less than the reference value Vref, so that the output of the comparator 161 is at a H level. On the other hand, when a short circuit occurs in the switch 141, the DC current value la becomes greater than the reference value Vref, and the output of the comparator 161 falls from the H level to the L level. The holding part 162 is a circuit that holds the output of the comparator 161 at the L level after the output of the comparator 161 falls from the H level to the L level.

The relay section 170 can be configured to include a switch control part 171, a relay switch 172, and a Zener diode 173. The relay switch 172 is disposed in the main wiring 136 and turns the connection state of the main wiring 136 on/off. The switch control part 171 supplies a control signal S3 for the relay switch 172 to a control terminal of the relay switch 172 in accordance with the determination result provided by the determination section 160. That is, when the current value of the DC current la is within a normal range, the control signal S3 is set to an ON level, and when the current value of the DC current la becomes abnormally large, the control signal S3 is set to an OFF level. When the relay switch 172 is turned off, the supply of the DC current la flowing through the boost coil 131 is cut off.

The Zener diode 173 is connected in the reverse direction between a node P3 on the main wiring 136 and the negative electrode 120n of the DC power supply 120. By providing the Zener diode 173, it is possible to absorb the surge voltage that occurs in the main wiring 136 when the supply of the DC current la is cut off by the relay switch 172. It is preferable that the node P3 of the Zener diode 173 is located between the boost coil 131 and the relay switch 172. In addition, it is preferable that the breakdown voltage of the Zener diode 173 is greater than the peak voltage of the node P3 when the switch 141 of the drive circuit 140 is operating normally. The Zener diode 173 may be omitted.

The positions of the boost coil 131 and the diode 132 in FIG. 2 and FIG. 3 are merely examples, and the boost coil 131 and the diode 132 may be provided at other positions on the main wiring 136 other than the above position. Specifically, the boost coil 131 may be provided upstream of the current detection section 150. The diode 132 may be provided upstream of the current detection section 150 or downstream of the relay section 170.

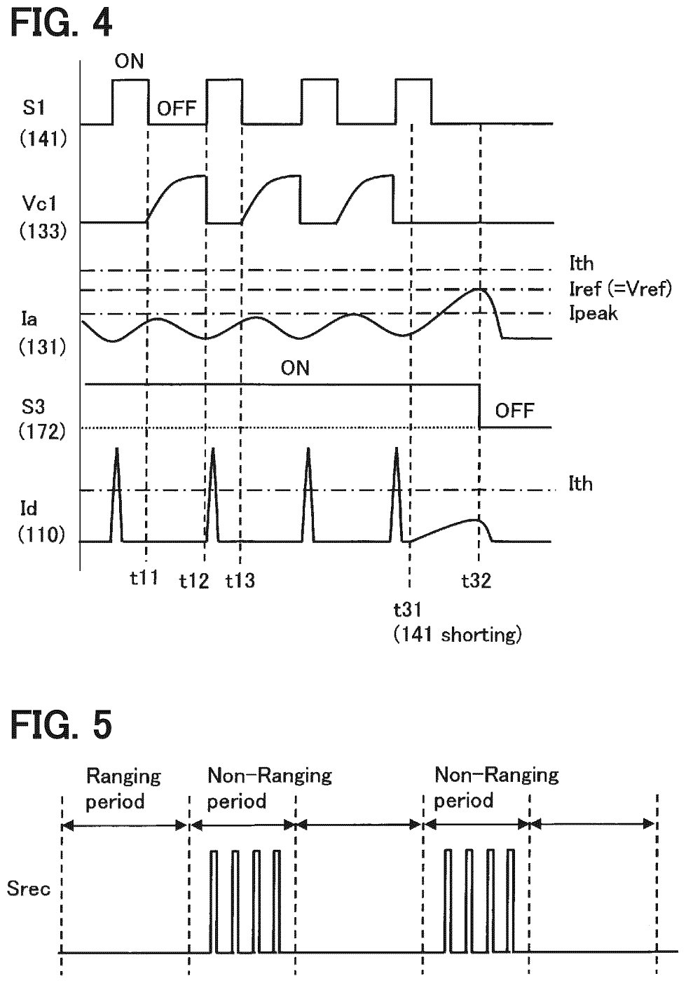

As shown in FIG. 4, the laser light emitting device 10 executes the light emission process in accordance with a distance measurement process performed by the controller 60 for measuring the distance to the object OB. FIG. 4 illustrates a control signal S1 of the switch 141 of the drive circuit 140, a voltage Vc1 across the boost capacitor 133, a DC current la flowing through the boost coil 131, a control signal S3 of the relay switch 172, and a current Id flowing through the laser diode 110.

In normal light emission process, when the switch 141 changes from the on state to the off state at time t11, the capacitor 133 is charged and the voltage Vc1 across the capacitor 133 rises and reaches a voltage higher than the voltage across the DC power supply 120. When the switch 141 is turned on at time t12, the charge stored in the capacitor 133 flows to the laser diode 110, and when the current Id flowing through the laser diode 110 becomes equal to or greater than the oscillation current threshold Ith, the laser diode 110 emits light. When the switch 141 changes from the on state to the off state at time t13, the voltage Vc1 across the capacitor 133 rises again. In this way, when the switch 141 is repeatedly turned on and off at a constant cycle, the laser diode 110 correspondingly emits light at a constant cycle. In normal light emission process without any malfunction, the DC current la flowing through the boost coil 131 is equal to or less than the peak current value Ipeak. This peak current value Ipeak is smaller than the oscillation current threshold Ith of the laser diode 110. In normal light emission process, the relay switch 172 is maintained in the on state.

On the other hand, when a short circuit occurs in the switch 141 that drives the laser diode 110 at time t31, the current value of the DC current la flowing through the boost coil 131 increases and exceeds the normal peak current value Ipeak. Then, when the current value of the DC current la becomes greater than the reference value Iref at time t32, the relay switch 172 switches from the on state to the off state, and the supply of the DC current la is cut off. This reference value Iref is a current value represented by a reference value Vref input to the comparator 161 in the circuit of FIG. 3. The reference value Iref is set to a value that is smaller than the oscillation current threshold Ith of the laser diode 110 and is larger than the peak current value Ipeak of the DC current la when the switch 141 is operating normally. Therefore, even if a short circuit occurs in the switch 141, the DC current la does not reach the oscillation current threshold Ith of the laser diode 110, and the laser diode 110 can be prevented from abnormally emitting light. As a result, safety standards for laser light (eye-safety standards) can be complied with.

Once the relay section 170 is in a cutoff state, it is preferable that the relay section 170 maintains the cutoff state even when the current value of the DC current la becomes equal to or smaller than the oscillation current threshold Ith. In the present embodiment, after the output of the comparator 161 falls to the L level, the holding part 162 holds the output of the comparator 161 at the L level, and accordingly the control signal S3 of the relay switch 172 is maintained at the off level. The function of maintaining the relay section 170 in the cutoff state may be realized by the relay section 170 instead of by the determination section 160.

As shown in FIG. 3, the voltage of the capacitor 133 is supplied to the controller 60 as a relay state signal SS. The controller 60 can use the relay state signal SS to determine whether or not the relay section 170 is in the cutoff state. For example, the controller 60 can determine whether the relay section 170 is in an OFF state by checking whether the voltage level of the relay state signal SS exceeds a preset reference value after the switch 141 is switched to the cutoff state. This reference value is set to a value smaller than the peak current value of the DC current la when the switch 141 is operating normally.

When the relay section 170 is in the cutoff state, it is preferable that the controller 60 notifies the user of the optical distance measurement device 100 that an abnormality or failure has occurred in the laser emission device 10 or the optical distance measurement device 100. This notification may be displayed, for example, on the meter panel of the vehicle in which the optical distance measurement device 100 is mounted.

The controller 60 further outputs a recovery signal Srec for recovering the cutoff state of the relay section 170 at a predetermined timing after the relay section 170 has been in the cutoff state. When the recovery signal Srec is input to the holding part 162 of the determination section 160, the output of the comparator 161 is forced to rise to the H level, and the cutoff state of the relay section 170 is released.

As shown in FIG. 5, it is preferable that the controller 60 generates the recovery signal Srec multiple times during a non-distance measurement period in which the optical distance measurement device 100 does not measure distance. The reason for generating the recovery signal Srec multiple times is to ensure that if the relay section 170 goes into the cutoff state due to some kind of noise, the cutoff state can be released without fail. However, the controller 60 may generate the recovery signal Srec only once.

The reason why the controller 60 generates the recovery signal Srec during the non-distance measurement period is to prevent the laser light generated when the cutoff state of the relay section 170 is released from the relay section 170 from being irradiated onto a person. That is, during the non-distance measurement period, even if the laser diode 110 emits light, the scanning range of the scanner 20 is within an angular range in which the laser light does not exit outside the optical distance measurement device 100. Therefore, even if the relay section 170 is connected in response to the recovery signal Srec and the laser diode 110 emits light, there is no risk of the laser light irradiating a person. However, the controller 60 may generate the recovery signal Srec during the distance measurement period.

As described above, in the first embodiment, when the current value of the DC current la flowing in the direction from the DC power supply 120 to the laser diode 110 is abnormal, the DC current la is cut off by the relay section 170, so that abnormal light emission of the laser diode 110 can be prevented.

### B. Second Embodiment

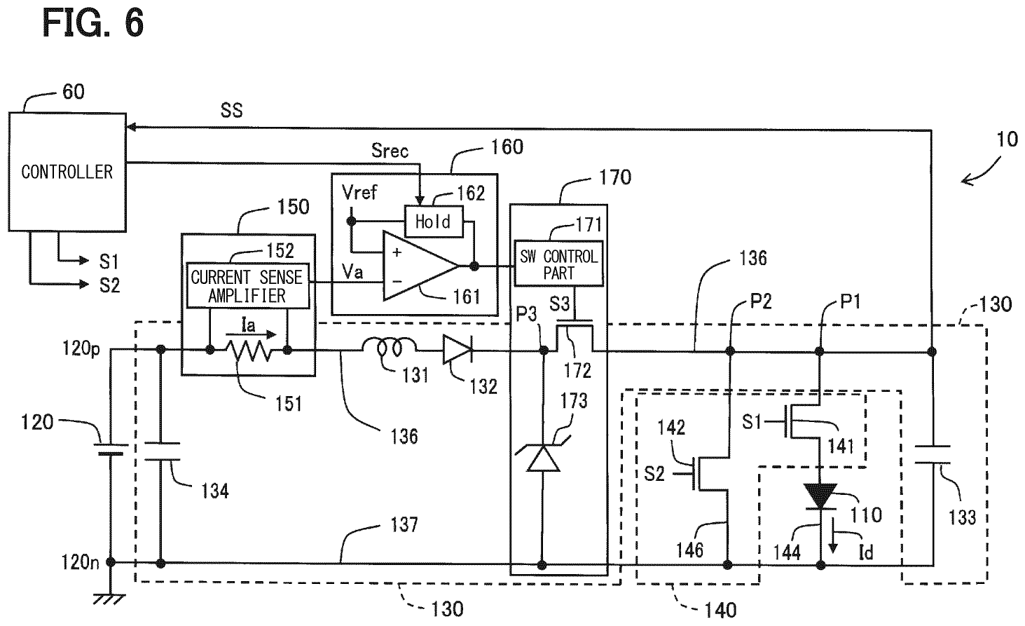

As shown in FIG. 6, the laser light emitting device 10 of the second embodiment has a configuration in which a second switch 142 is added to the laser light emitting device of the first embodiment shown in FIG. 3, and the other configurations are the same as those of the first embodiment.

The second switch 142 and the first switch 141 configure the drive circuit 140. The second switch 142 is connected in parallel with the series connection of the laser diode 110 and the switch 141. In the example of FIG. 6, the second drive wiring 146 on which the second switch 142 is provided is arranged to connect between a node P2 downstream of the relay section 170 on the main wiring 136 and the negative electrode 120n of the DC power supply 120. A control signal S2 is supplied to a control terminal of the second switch 142 from the controller 60.

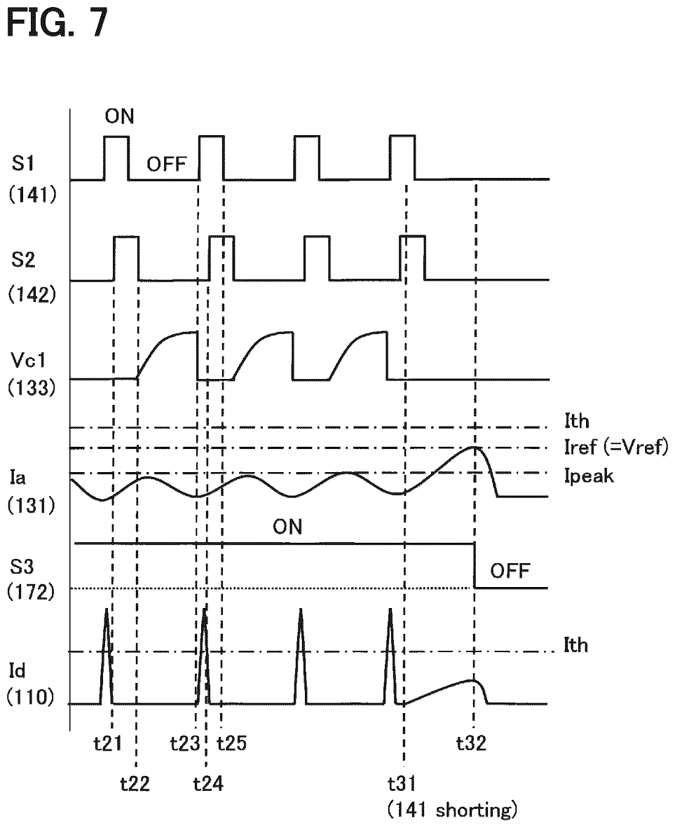

As shown in FIG. 7, the operation of the light emission process in the second embodiment is similar to that of the first embodiment shown in FIG. 4, except that the on/off operation of the second switch 142 is added. The second switch 142 switches from the OFF state to the ON state at time t21, turns OFF at time t22, and turns ON again at time t24. On the other hand, the first switch 141 switches from the OFF state to the ON state at time t23, and returns to the OFF state at time t25. That is, the first switch 141 switches from the off state to the on state during the period in which the second switch 142 is in the off state, and switches from the on state to the off state during the period in which the second switch 142 is in the on state.

In the second embodiment, even if the first switch 141 does not turn on for some reason, the second switch 142 turns on, and the charge accumulated in the capacitor 133 is discharged via the second switch 142. As a result, application of an overvoltage to the laser diode 110 can be suppressed.

In addition, if it is assumed that the second switch 142 is switched to the on state after the first switch 141 is turned off, the capacitor 133 is charged as the first switch 141 is turned off, and then, when the second switch 142 is turned on, the capacitor 133 is discharged via the second switch 142. On the other hand, according to the light emission process of the second embodiment, the first switch 141 is switched to the off state after the second switch 142 is turned on, so that the charging of the capacitor 133 that does not contribute to boosting the voltage of the capacitor 133 can be reduced. In this manner, by adjusting the timing of switching between the on/off states of the two switches 141, 142, the charging of the capacitor 133 can be controlled with higher precision. In other words, the DC current la flowing through the booster circuit 130 can be controlled with higher precision by using the second switch 142.

In FIG. 7, the process after time t31 when a short circuit failure occurs in the first switch 141 is similar to the process in the first embodiment shown in FIG. 4, and therefore a description thereof will be omitted. In the second embodiment, the recovery process using the recovery signal Srec can be executed in the same manner as in the first embodiment.

The second embodiment also has the same effects as the first embodiment described above. Furthermore, in the second embodiment, by using the second switch 142, the DC current la flowing through the booster circuit 130 can be controlled with higher precision.

### C. Third Embodiment

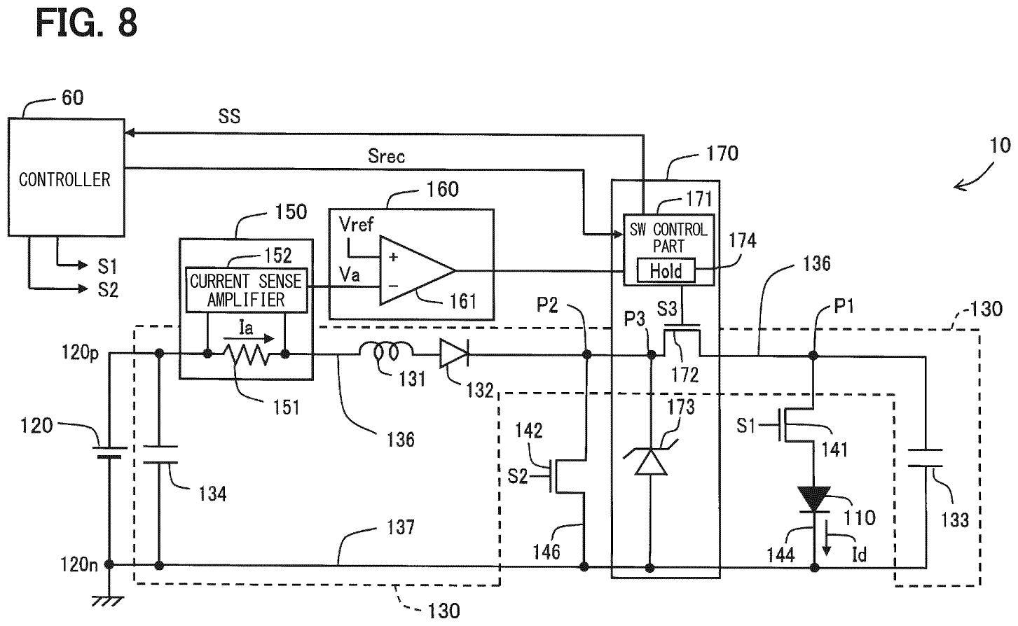

As shown in FIG. 8, the laser light emitting device 10 of the third embodiment differs from the laser light emitting device of the second embodiment shown in FIG. 6 in the following differences (a) to (d), and the other configurations are the same as those of the second embodiment.
(a) The second drive wiring 146 including the second switch 142 is connected to the upstream side of the relay section 170, not to the downstream side of the relay section 170.
(b) The holding part 162 of the determination section 160 is omitted, and a holding part 174 is added to the switch control part 171 of the relay section 170. After the control signal S3 of the relay switch 172 drops to the OFF level once, the holding part 174 maintains the control signal S3 at the OFF level. In other words, the holding part 174 has a function of maintaining the relay section 170 in the cutoff state.
(c) The recovery signal Srec is supplied to the relay section 170 instead of the determination section 160. When the recovery signal Srec is supplied to the switch control part 171, the level of the control signal S3 held in the holding part 174 is switched from the OFF level to the ON level.
(d) A signal indicating the level of the control signal S3 of the relay switch 172 is supplied from the switch control part 171 to the controller 60 as a relay state signal SS.

As can be understood from the circuit configurations of the second and third embodiments, the laser light emitting device 10 can be configured so that a recovery signal Srec for canceling the cutoff state of the relay section 170 is supplied to the determination section 160 or the relay section 170.

The laser light emitting device 10 of the third embodiment operates in substantially the same manner as the laser light emitting device of the second embodiment, and therefore a description thereof will be omitted. Moreover, the laser light emitting device 10 of the third embodiment also provides substantially the same effects as the laser light emitting device of the second embodiment.

### D. Other Embodiments

The present disclosure should not be limited to the embodiments or modifications described above, and various other embodiments may be implemented without departing from the scope of the present disclosure. For example, the technical features in each embodiment corresponding to the technical features in the form described in the summary may be used to solve some or all of the above-described problems, or to provide one of the above-described effects. In order to achieve a part or all, replacement or combination can be appropriately performed. Also, if the technical features are not described as essential in the present specification, they can be deleted as appropriate.

What is claimed is:

1. A laser light emitting device, comprising:
a laser diode;
a DC power supply;
a booster circuit configured to boost a DC voltage supplied from the DC power supply via a main wiring connected to a positive electrode of the DC power supply and supplies boosted DC voltage to the laser diode;
a drive circuit including a drive wiring connecting the main wiring and a negative electrode of the DC power supply, and a first switch for switching between a conducting state and a non-conducting state of the laser diode, the laser diode and the first switch being connected in series to the drive wiring;
a current detection section configured to detect a current value of a direct current flowing on the main wiring in a direction from the DC power supply to the laser diode;
a determination section configured to determine whether a current value is normal or abnormal; and
a relay section configured to cut off a supply of the direct current in response to a determination result of the determination section; wherein
the drive circuit includes a second switch connected in parallel with a series connection of the laser diode and the first switch, and
the first switch is configured to switch from an off state to an on state during a period in which the second switch is in an off state, and to switch from an on state to an off state during a period in which the second switch is in an on state.

2. The laser light emitting device according to claim 1, wherein
the determination section is configured to compare a preset determination value with a current value and determine that the current value is abnormal when the current value is greater than the preset determination value, and
the determination value is set to a value smaller than an oscillation current threshold of the laser diode and larger than a peak current value of DC current when the first switch is operating normally.

3. The laser light emitting device according to claim 1, further comprising,
a controller configured to transmit a recovery signal to the determination section or the relay section to release a cutoff state of the relay section after the relay section cuts off the supply of DC current.

4. The laser light emitting device according to claim 1, wherein
the booster circuit includes a boost coil provided in the main wiring, and a forward-connected diode provided downstream of the boost coil, and
the relay section includes a relay switch connected to a downstream side of the boost coil in the main wiring, and a reverse-connected Zener diode provided between a node between the boost coil and the relay switch and the negative electrode.

5. A optical distance measurement device, comprising:
a laser light emitting device including a laser diode;
a light receiver configured to receive light reflected by an object from the laser light emitted from the laser diode; and
a calculator configured to calculate a distance to the object using a time period from when the laser light is emitted to when a reflected light is received;
wherein
the laser light emitting device includes
a DC power supply,
a booster circuit configured to boost a DC voltage supplied from the DC power supply via a main wiring connected to a positive electrode of the DC power supply and supplies boosted DC voltage to the laser diode,
a drive circuit including a drive wiring connecting the main wiring and a negative electrode of the DC power supply, and a first switch for switching between a conducting state and a non-conducting state of the laser diode, the laser diode and the first switch being connected in series to the drive wiring,
a current detection section configured to detect a current value of a direct current flowing on the main wiring in a direction from the DC power supply to the laser diode,
a determination section configured to determine whether a current value is normal or abnormal, and
a relay section configured to cut off a supply of the direct current in response to a determination result of the determination section,
the drive circuit includes a second switch connected in parallel with a series connection of the laser diode and the first switch, and
the first switch is configured to switch from an off state to an on state during a period in which the second switch is in an off state, and to switch from an on state to an off state during a period in which the second switch is in an on state.
